(19) United States
(12) Patent Application Publication
(10) Pub. No.: US 2017/0179127 A1
(43) Pub. Date: Jun. 22, 2017

(54) SEMICONDUCTOR STRUCTURE HAVING SILICON GERMANIUM FINS AND METHOD OF FABRICATING SAME

(71) Applicant: GLOBALFOUNDRIES INC., Grand Cayman (KY)

(72) Inventors: Judson R. Holt, Ballston Lake, NY (US); Jody A. Fronheiser, Delmar, NY (US); Kangguo Cheng, Schenectady, NY (US); Shogo Mochizuki, Clifton Park, NY (US); Stephen W. Bedell, Wappingers Falls, NY (US)

(21) Appl. No.: 14/974,136

(22) Filed: Dec. 18, 2015

(51) Int. Cl. H01L 27/092; H01L 29/15; H01L 21/8238; H01L 29/10

(52) U.S. Cl. CPC H01L 27/0924; H01L 29/1054; H01L 29/157; H01L 21/823821; H01L 21/823807; H01L 21/823814

(57) ABSTRACT

An aspect of the disclosure includes a semiconductor structure comprising: a set of fins on a substrate, the set of fins including a relaxed silicon germanium layer; and a dielectric between each fin in the set of fins; wherein each fin in a n-type field effect transistor (nFET) region further includes a strained silicon layer over the relaxed silicon germanium layer of each fin in the nFET region; wherein each fin in a p-type field effect transistor (pFET) region further includes a strained silicon germanium layer over the relaxed silicon germanium layer of each fin in the pFET region.

### BACKGROUND

Technical Field

The present disclosure relates to semiconductor structures, and more particularly, to semiconductor structures having silicon germanium fins and methods of fabricating the same.

Related Art

Semiconductor fabrication may begin with providing many semiconductor structures, such as capacitors, transistors, and/or buried interconnects on silicon substrates. In some instances, it may be desirous to provide those semiconductor structures with silicon germanium channels to increase mobility and performance of the device. To accomplish this, a silicon germanium layer may be grown on a silicon substrate. One challenge with forming silicon germanium channels includes growing a relaxed silicon germanium layer comprising a low amount of germanium (approximately 5% to approximately 40% germanium) on the silicon substrate.

Typically, a very thick (several microns), strain relaxed, buffer layer of silicon germanium is grown on the silicon substrate. As the silicon germanium layer is grown, it maintains the crystal lattice of the silicon substrate. In order to achieve a relaxed layer of silicon germanium, the silicon germanium layer is grown until it reaches a thickness that causes enough strain such that defects or cracks are created. This process relies on the slow germanium gradient to relax the film. This process is both time consuming and costly.

### SUMMARY

A first aspect of the disclosure includes a method of fabricating a semiconductor structure. The method may include: forming a silicon germanium superlattice over a substrate; forming a set of fins within the silicon germanium superlattice; forming a dielectric between each fin in the set of fins; forming a strained silicon layer over a first portion of the set of fins and the dielectric therebetween; and forming a strained silicon germanium layer over a second portion of the set of fins and the dielectric therebetween.

A second aspect of the disclosure includes a method of fabricating a semiconductor structure. The method may include: forming a first strained silicon germanium layer on a substrate; implanting a first species to a depth of the interface of the first strained silicon germanium layer and the substrate; forming a set of fins in the first strained silicon germanium layer; forming a dielectric between each fin in the set of fins; annealing the set of fins; removing a portion of each fin; forming a strained silicon layer over a first portion of the set of fins and the dielectric therebetween; and forming a second strained silicon germanium layer over a second portion of the set of fins and the dielectric therebetween.

A third aspect of the disclosure includes a semiconductor structure comprising: a set of fins on a substrate, the set of fins including a silicon germanium layer; and a dielectric between each fin in the set of fins; wherein each fin in a n-type field effect transistor (nFET) region further includes a strained silicon layer over the silicon germanium layer of each fin in the nFET region; wherein each fin in a p-type field effect transistor (pFET) region further includes a strained silicon germanium layer over the silicon germanium layer of each fin in the pFET region.

### BRIEF DESCRIPTION OF THE DRAWINGS

The embodiments of this disclosure will be described in detail, with reference to the following figures, wherein like designations denote like elements, and wherein:

FIGS. 1-7 show a semiconductor structure undergoing aspects of a method as described herein.

FIGS. 8-14 show a semiconductor structure undergoing aspects of a method alternative to the method as described with respect to FIGS. 2-7.

FIGS. 15-21 show a semiconductor structure undergoing aspects of another method as described herein.

FIGS. 22-26 show a semiconductor structure undergoing aspects of another method as described herein.

### DETAILED DESCRIPTION

Aspects of the present disclosure relate to semiconductor structures, and more particularly, to semiconductor structures having silicon germanium fins and methods of fabricating the same. Specifically, the semiconductor structure described herein is a thin, strain relaxed buffer layer that is achieved faster and less costly when compared to conventional approaches for achieving a strain relaxed buffer layer.

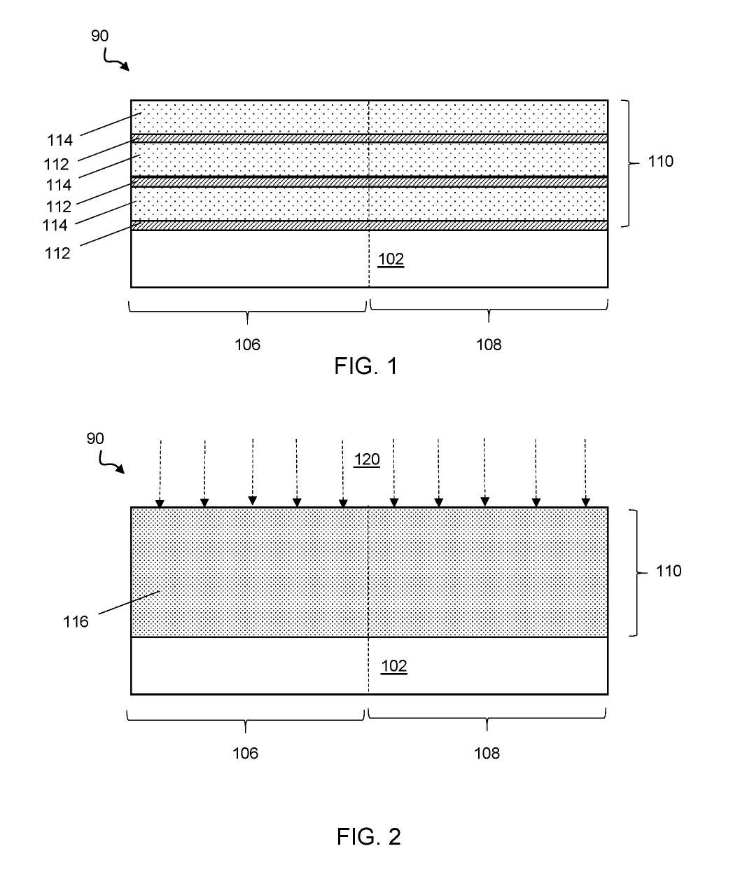

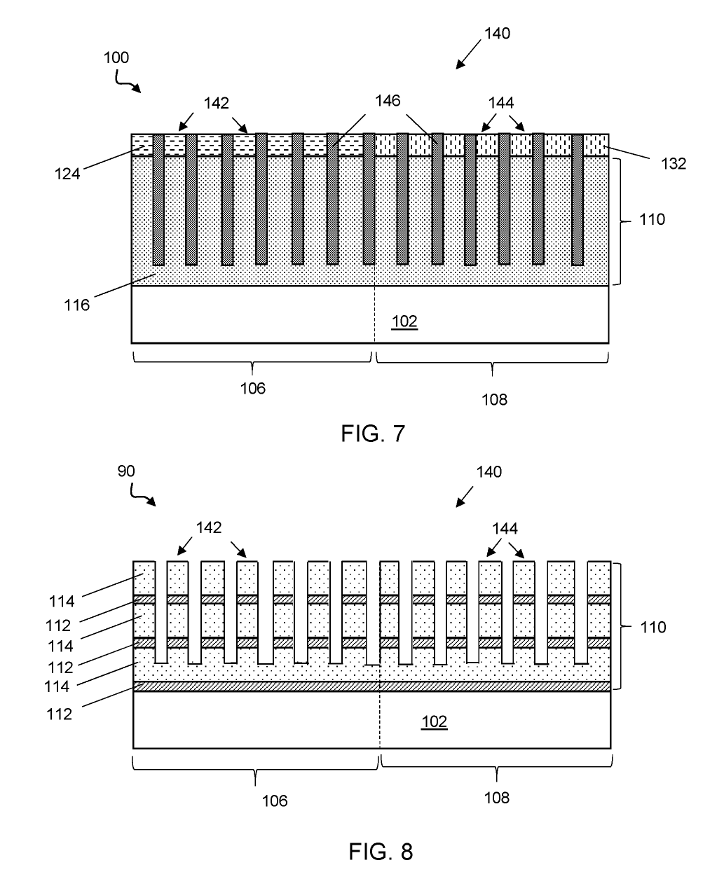

Referring to FIGS. 1-7, a method for forming a semiconductor structure 100 (FIG. 7) according to aspects of the disclosure will now be described. The method may start by forming a structure 90 including a silicon germanium superlattice 110 over a substrate 102. It will be understood that when an element as a layer, region or substrate is referred as being “over” another element, it can be directly on the other element or intervening elements may be present. It will also be understood that when an element is referred to as being “connected” or “coupled” to another element, it can be directly connected or couple to the other element or intervening elements may be present. Substrate 102 may include but is not limited to silicon, germanium, silicon germanium, silicon carbide, and those consisting essentially of one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions, each greater than or equal to zero and X1+X2+X3+Y1+Y2+Y3+Y4=1 (1 being the total relative mole quantity). Other suitable substrates include II-VI compound semiconductors having a composition Zn_{A1}Cd_{A2}Se_{B1}Te_{B2}, where A1, A2, B1, and B2 are relative proportions each greater than or equal to zero and A1+A2+B1+B2=1 (1 being a total mole quantity). Structure 90 may include a n-type field effect transistor (nFET) region 106 and a p-type field effect transistor (pFET) region 108.

Silicon germanium superlattice 110 may include alternating germanium layers 112 and silicon layers 114 over substrate 102. Silicon germanium superlattice 110 may be formed via, for example, epitaxial growth and/or deposition. The terms “epitaxial growth and/or deposition” and “epitaxially formed and/or grown” mean the growth of a semiconductor material on a deposition surface of a semiconductor material, in which the semiconductor material being grown may have the same crystalline characteristics as the semiconductor material of the deposition surface. In an epitaxial deposition process, the chemical reactants provided by the source gases are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material may have the same crystalline characteristics as the deposition surface on which it may be formed. For example, an epitaxial semiconductor material deposited on a {100} crystal surface may take on a {100} orientation. In some embodiments, epitaxial growth and/or deposition processes may be selective to forming on semiconductor surfaces, and may not deposit material on dielectric surfaces, such as silicon dioxide or silicon nitride surfaces.

Germanium layers 112 may be formed, for example, at a temperature of approximately 200° C. to approximately 600° C., or more particularly, approximately 350° C., at a pressure of approximately 1 Torr to approximately 1000 Torr, or more particularly 300 Torr. Process gases that may be used during formation of germanium layers 112 may include, but are not limited to: hydrogen (H₂), germane (GeH₄), germanium chloride (GeCl₄), and hydrogen chloride (HCl). Silicon layers 114 may be formed, for example, at a temperature of approximately 400° C. to approximately 900° C., or more particularly, approximately 700° C., at a pressure of approximately 1 Torr to approximately 1000 Torr, or more particularly 10 Torr. Process gases that may be used during formation of silicon layers 114 may include, but are not limited to: hydrogen (H₂), silane (SiH₄), disilane (Si₂H₆), dichlorosilane (SiCl₂H₂), hydrogen chloride (HCl).

The relative thickness of each silicon layer 114 compared to the thickness of each germanium layer 112 may change depending on the desired final percent of germanium. For instance, in the case that the final composition is 25% germanium, silicon layer 114 may have a thickness that is approximately 4 times the thickness of each germanium layer 112. In this embodiment, each germanium layer 112 may have a thickness of approximately 1 nanometer (nm) to approximately 10 nm and each silicon layer 114 may have a thickness of approximately 4 nm to approximately 40 nm. Silicon germanium superlattice 110 may include a total thickness of approximately 10 nm to approximately 1000 nm. While only three germanium layers 112 and three silicon layers 114 are shown, any number of germanium layers 112 and silicon layers 114 may be formed without departing from aspects of the disclosure. As used herein “approximately” is intended to include values, for example, within 10% of the stated values.

Alternating germanium layers 112 and silicon layers 114 in this way results in a relaxed silicon germanium superlattice 110. Specifically, at each interface of a respective germanium layer 112 and silicon layer 114 there is an opportunity for the lattice to break thereby decoupling the crystal structure of silicon germanium superlattice 110 resulting in a relaxed silicon germanium superlattice 110 as opposed to a strained superlattice.

As shown in FIG. 2, structure 90 may undergo a thermal treatment process such as an anneal. For example, a laser or flash anneal 120 may be performed on structure 90. Anneal 120 may be performed at a temperature of approximately 900° C. to approximately 1200° C. for approximately 1 hour to approximately 24 hours. Anneal 120 results in the thermal mixing of germanium layers 112 (FIG. 1) and silicon layers 114 (FIG. 1) such that silicon germanium superlattice 110 is composed of a single composition of relaxed silicon germanium 116. Relaxed silicon germanium 116 may include a low percent of germanium. For example, relaxed silicon germanium 116 may include approximately 10% germanium to approximately 50% germanium, or more particularly 25% germanium. In some embodiments, an oxide layer (not shown), e.g., silicon dioxide, may first be formed (e.g., via growth and/or deposition) over the uppermost silicon layer 114 (FIG. 1) prior to the performing of anneal 120.

As used herein, and unless otherwise noted, the term “depositing” may include any now known or later developed techniques appropriate for the material to be deposited including but are not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metalorganic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

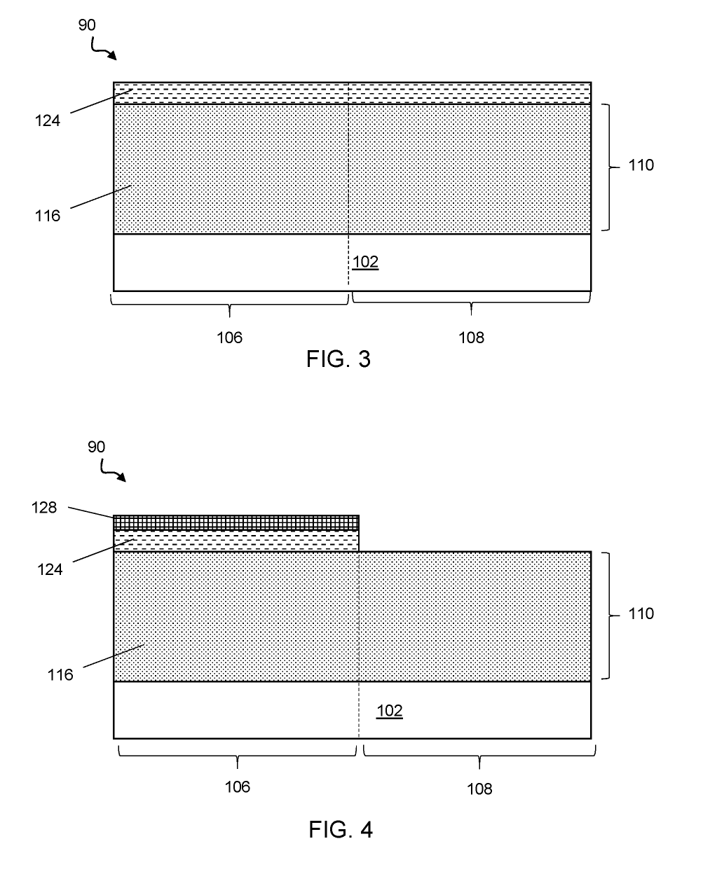

Referring now to FIG. 3, a strained silicon layer 124 may be formed over silicon germanium superlattice 110. As will be described herein, strained silicon layer 124 may be used with an nFET. After strained silicon layer 124 is formed, strained silicon layer 124 may be patterned as shown in FIG. 4. For example, a mask 128, e.g. hardmask, may be formed over strained silicon layer 124, patterned, and etched to exposed portions of silicon germanium superlattice 110 thereunder. As used herein, “etching” may include any now known or later developed techniques appropriate for the material to be etched including but not limited to, for example: anisotropic etching, plasma etching, sputter etching, ion beam etching, reactive-ion beam etching and reactive-ion etching (RIE). In the embodiment shown in FIG. 4, mask 128 and strained silicon layer 124 may be etched to expose silicon germanium superlattice 110 of pFET region 108.

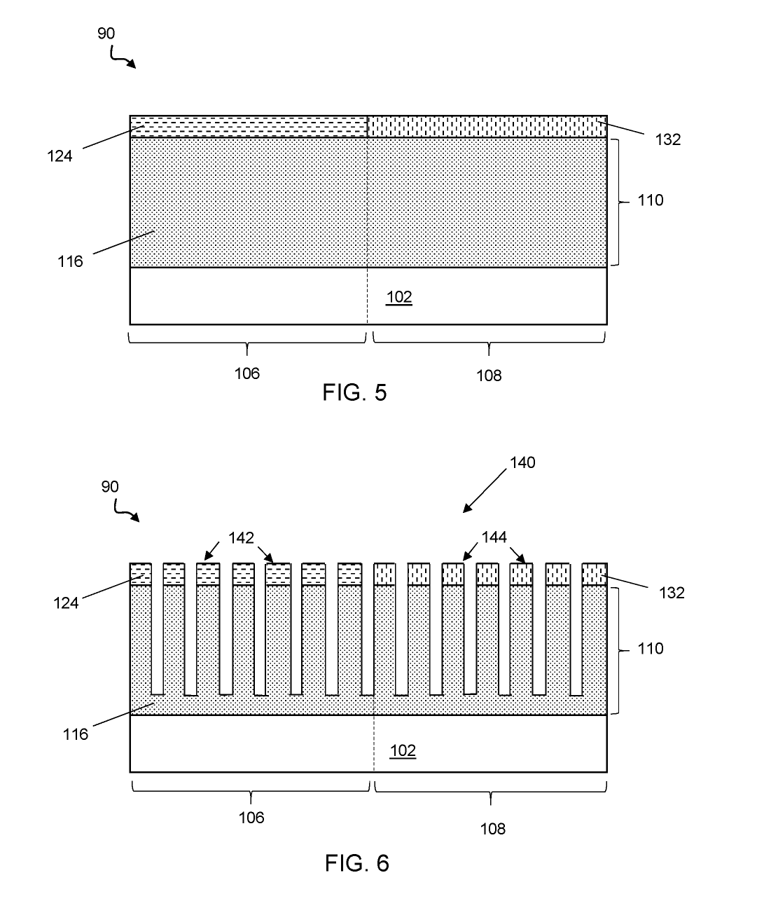

As shown in FIG. 5, a strained silicon germanium layer 132 may be formed (e.g., via epitaxial growth and/or deposition) over the exposed silicon germanium superlattice 110. That is, strained silicon germanium layer 132 may be formed over silicon germanium superlattice 110 of pFET region 108. Strained silicon germanium layer 132 may include a high percent of germanium (approximately 40% to approximately 80%). While it has been shown and described as strained silicon layer 124 being formed prior to the formation of strained silicon germanium layer 132, it is to be understood that strained silicon germanium layer 132 may be formed prior to strained silicon layer 124 in other embodiments without departing from aspects of the disclosure. That is, strained silicon germanium layer 132 may be formed on silicon germanium superlattice 110 after the performing of anneal 120 (FIG. 2). Strained silicon germanium layer 132 may be patterned as described with respect to FIGS. 3-4 to exposed silicon germanium superlattice 110 of nFET region 106. Subsequently, strained silicon layer 124 may be formed over the exposed silicon germanium superlattice 110 of nFET region 106.

As shown in FIG. 6, after strained silicon layer 124 and strained silicon germanium layer 132 are formed, a set of fins 140 may be formed, e.g., via conventional etching and masking techniques known in the art and/or described herein. Set of fins 140 may include fins 142 in nFET region 106 and fins 144 in pFET region 108. Overlying each fin 142, 144 may be a hard mask (not shown), which can be formed according to known techniques to shield each fin 142, 144 in set of fins 140 during subsequent processing steps. It is understood that the use of the hard mask over each fin 142, 144 is optional in some embodiments. The portions of fins 142, 144 where the hard mask is not employed, enables the subsequent formation of gate stack (not shown) which will wrap around each fin 142, 144 as known in the art. Prior to forming the gate stack over the exposed fins 142, 144, fins 142, 144 may be lightly doped with dopants opposite of the transistor type which facilitate the formation of channel regions (not shown). Further, as shown in FIG. 7, a dielectric 146, may be formed, e.g., via deposition, between each fin 142, 144 in set of fins 140. Dielectric 146 may include, for example, an oxide, e.g., silicon dioxide, or a nitride, e.g., silicon nitride, or combinations thereof.

The resulting semiconductor structure 100 that is formed after undergoing the processing steps shown and described with respect to FIGS. 1-7 may include a set of fins 140 on a substrate 102 and a dielectric 146 between each fin 142, 144 in set of fins 140. Each fin 142 in nFET region 106 may include a relaxed silicon germanium 116 of a silicon germanium superlattice 110 and a strained silicon layer 142 on top thereof. Each fin 144 in pFET region 108 may include a relaxed silicon germanium 116 of a silicon germanium superlattice 110 and a strained silicon germanium layer 144 on top thereof.

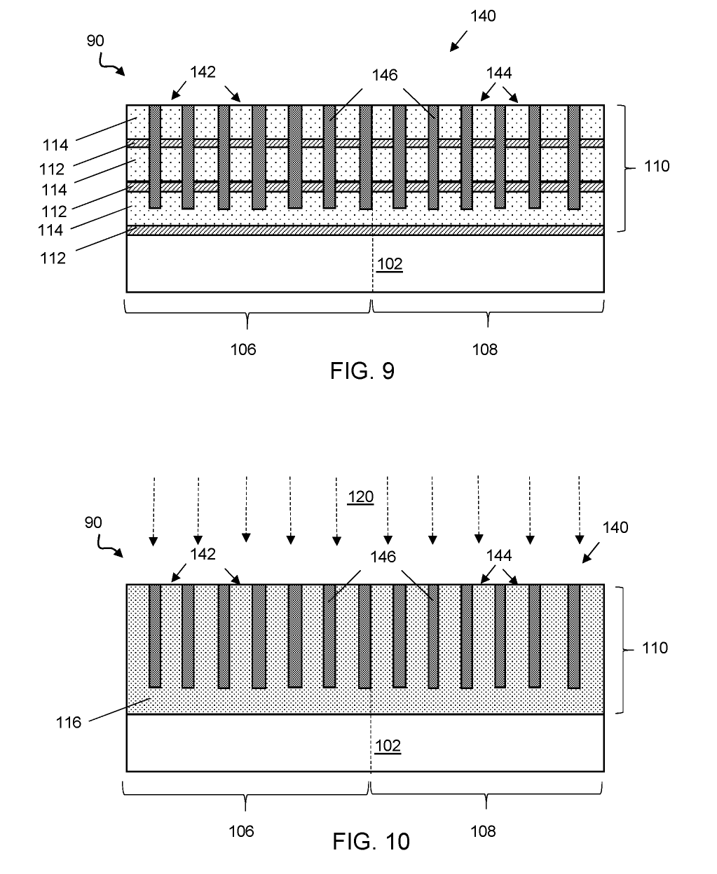

FIGS. 8-14 show structure 90 undergoing aspects of a method alternative to the method as described with respect to FIGS. 2-7, wherein the resulting semiconductor structure 100 according to this embodiment is shown in FIG. 14. In this embodiment, after formation of silicon germanium superlattice 110 as discussed with respect to FIG. 1, set of fins 140 may be formed as shown in FIG. 8. That is, set of fins 140 may be formed after the formation of the alternating germanium layers 112 and silicon layers 114. Germanium layers 112, silicon layers 114, and set of fins 140 may be formed as described herein with respect to FIGS. 1 and 6. As shown in FIG. 9, a dielectric 146 may be formed between each fin 142, 144 as described with respect to FIG. 7.

Referring now to FIG. 10, a thermal treatment process, e.g., an anneal 120, may be performed on structure 90 as described with respect to FIG. 2. That is, this embodiment differs from the embodiment of FIGS. 2-7 in that anneal 120 is performed after the formation of set of fins 140 rather than prior to the formation of set of fins 140. Anneal 120 results in the thermal mixing of germanium layers 112 (FIG. 9) and silicon layers 114 (FIG. 9) such that silicon germanium superlattice 110 is composed of a single composition of relaxed silicon germanium 116. Relaxed silicon germanium 116 may include a low percent of germanium. That is, relaxed silicon germanium 116 may include approximately 10% germanium to approximately 50% germanium, or more particularly 25% germanium. In some embodiments, an oxide layer (not shown), e.g., silicon dioxide, may first be formed (e.g., via growth and/or deposition) over the uppermost silicon layer 114 (FIG. 9) prior to the performing of anneal 120.

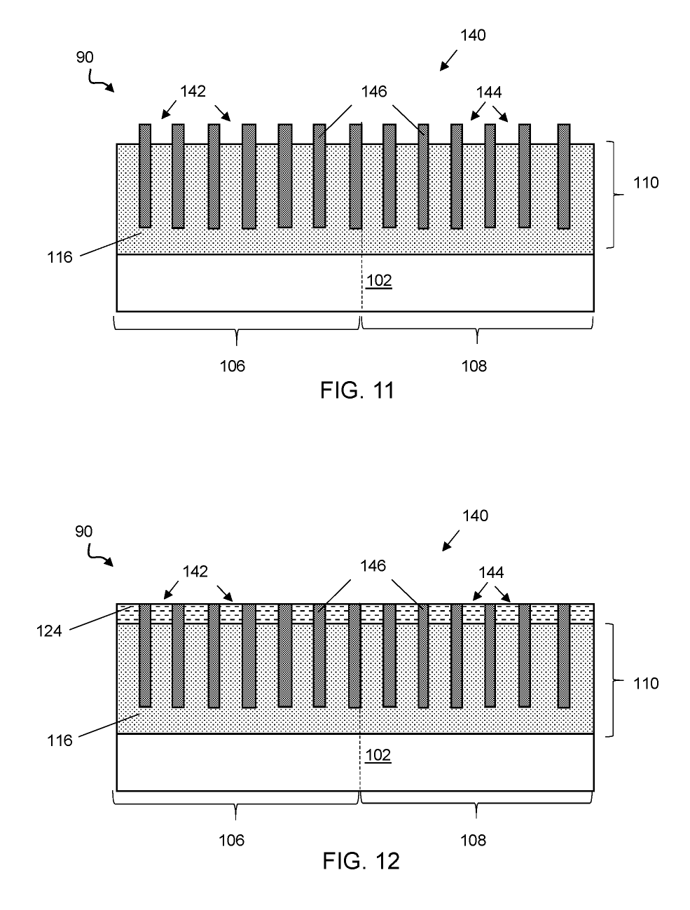

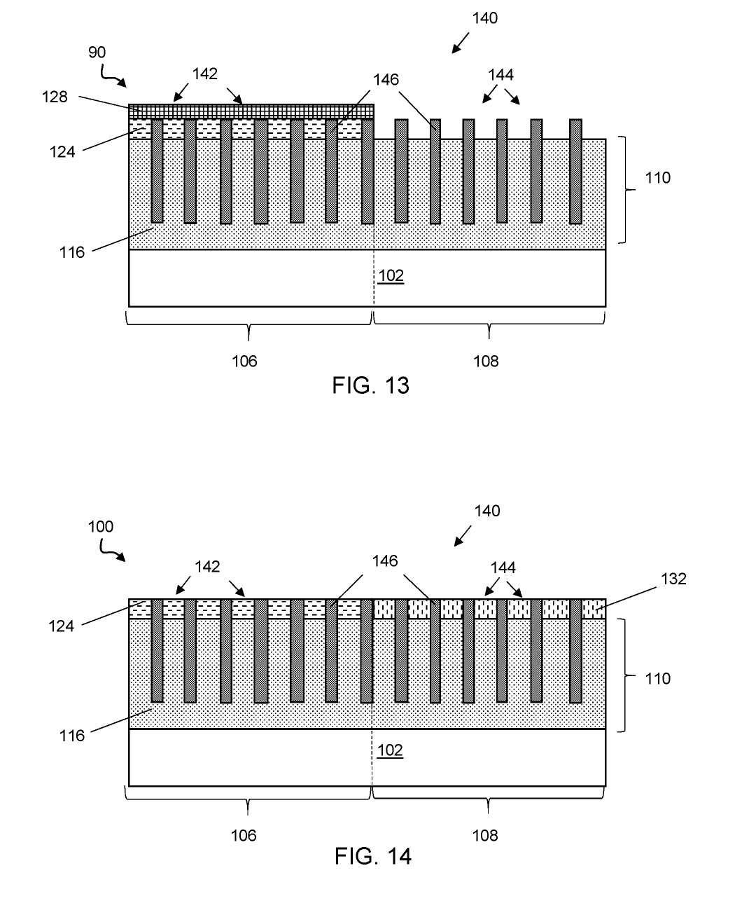

As shown in FIG. 11, set of fins 140 may be recessed, e.g., via etching, such that each fin 142, 144 in set of fins 140 has a height less than that a height of each dielectric 146 therebetween. For example, a mask (not shown), may be formed over structure 90, patterned, and etched to expose fins 142, 144. Subsequently, a portion of fins 142, 144 may be removed. After fins 142, 144 are recessed, a strained silicon layer 124 may be formed (e.g., via epitaxial growth and/or deposition) over exposed silicon germanium superlattice 110 of each fin 142, 144 to a height of dielectric 146 as shown in FIG. 12. Further, strained silicon layer 124 may be patterned to expose a portion of relaxed silicon germanium layer 116. For example, as shown in FIG. 13, a mask 128, e.g. hardmask, may be formed over strained silicon layer 124, patterned, and etched to expose fins 142, 144 and dielectric 146 thereunder of pFET region 108.

As shown in FIG. 14, a strained silicon germanium layer 132 may be formed (e.g., via epitaxial growth and/or deposition) over the exposed silicon germanium superlattice 110 of each fin 142, 144 to a height of dielectric 146 as discussed with respect to FIG. 7. That is, strained silicon germanium layer 132 may be formed over silicon germanium superlattice 110 of pFET region 108. Strained silicon germanium layer 132 may include a high percent of germanium (approximately 40% to approximately 80%). While it has been shown and described as strained silicon layer 124 being formed prior to the formation of strained silicon germanium layer 132, it is to be understood that strained silicon germanium layer 132 may be formed prior to strained silicon layer 124 in other embodiments without departing from aspects of the disclosure. That is, strained silicon germanium layer 132 may be formed on silicon germanium superlattice 110 after the recessing of set of fins 140. Strained silicon germanium layer 132 may be patterned as described with respect to FIG. 13 to expose silicon germanium superlattice 110 of nFET region 106. Subsequently, strained silicon layer 124 may be formed over the exposed silicon germanium superlattice 110 of nFET region 106.

The resulting semiconductor structure 100 after undergoing processing steps shown and described with respect to FIGS. 8-14 may include a set of fins 140 on a substrate 102 and a dielectric 146 between each fin 142, 144 in set of fins 140. Each fin 142 in nFET region 106 may include a silicon germanium superlattice 100 including relaxed silicon germanium 116 and a strained silicon layer 142 on top thereof. Each fin 144 in pFET region 108 may include a silicon germanium superlattice 100 including relaxed silicon germanium 116 and a strained silicon germanium layer 144 on top thereof.

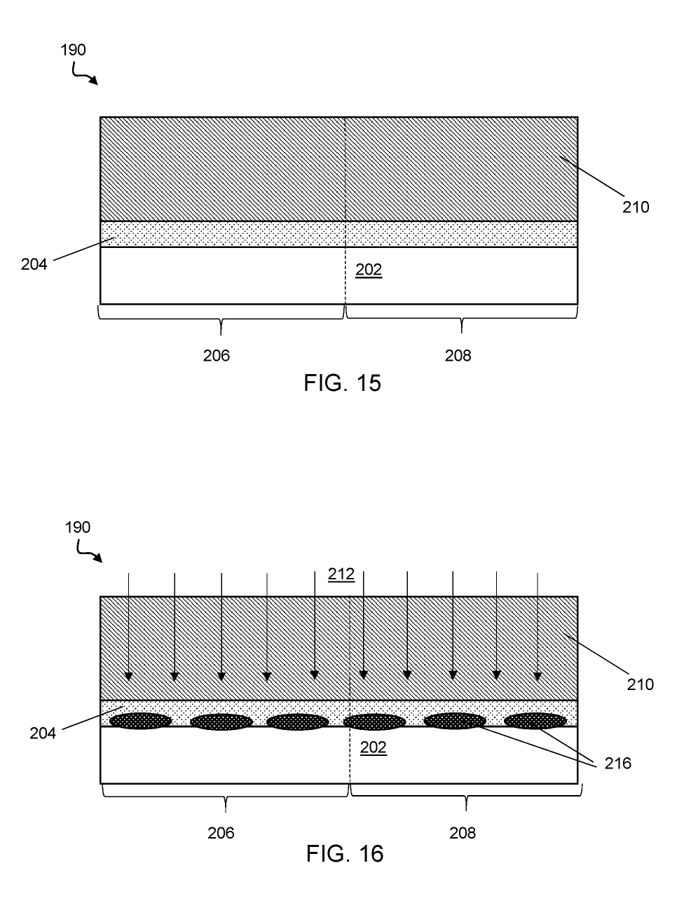

Referring now to FIGS. 15-19, a semiconductor structure 190 undergoing aspects of another method as described herein is shown. In this embodiment, a silicon germanium carbon layer 204 is formed, e.g., via epitaxial growth and/or deposition, on a substrate 202 as shown in FIG. 15. Substrate 202 may include any of the materials listed herein relative to substrate 102 (FIG. 1). Silicon germanium carbon layer 204 may include approximately 0.5% carbon to approximately 1.5% carbon. Further, a strained silicon germanium layer 210 may be formed, e.g., via epitaxial growth and/or deposition, over silicon germanium carbon layer 204. Strained silicon germanium layer 210 may include a low percentage of germanium. That is, strained silicon germanium layer 210 may include approximately 10% germanium to approximately 50% germanium, or more particularly 25% germanium.

Strained silicon germanium layer 210 and silicon germanium carbon layer 204 may be formed at a temperature of approximately 400° C. to approximately 800° C., or more particularly, approximately 500° C., at a pressure of approximately 1 Torr to approximately 1000 Torr, or more particularly 10 Torr. Process gases that may be used during formation of germanium layers 112 may include, but are not limited to: hydrogen (H₂), germane (GeH₄), hydrogen chloride (HCl), silane (SiH₄), disilane (Si₂H₆), dichlorosilane (SiCl₂H₂), monomethylsilane (SiH₃CH₃), and acetylene (C2H2).

As shown in FIG. 16, an implanted species 212 may be implanted to a depth of the interface of silicon germanium carbon layer 204 and the substrate 202. Implanted species 212 may include, for example, at least one of: hydrogen (H+) and helium (He). Implanted species 212 may be implanted at a dose of approximately 1e16 ions/cm² to approximately 5e16 ions/cm², or more particularly, approximately 2e16 ions/cm² at an energy range of, for example, approximately 10 electronvolts (eV) to approximately 30 eV. In another embodiment, implanted species 212 may include hydrogen (H₂). In this embodiment, the does range of hydrogen (H₂) may be implanted at may be approximately half of that which is described with respect to hydrogen (H+) and helium (He). The implanting results in silicon germanium carbon layer 204 decoupling from the crystal lattice of substrate 202 thereby causing defects 216 at the interface of silicon germanium carbon layer 204 and substrate 202. Specifically, micro-cavities (not shown) may be formed at the interface of silicon germanium carbon layer 204 and substrate 202 such that the crystal lattice of silicon germanium carbon layer 204 fractures but does not completely decouple from substrate 202 or cause delamination.

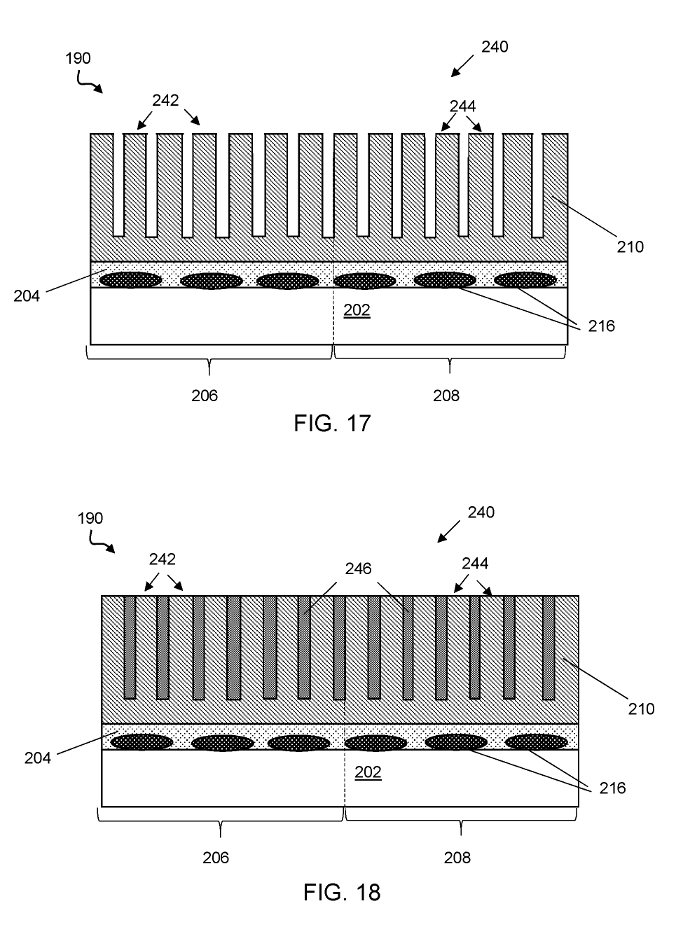

As shown in FIG. 17, a set of fins 240 may be formed from strained silicon germanium layer 210 e.g., via conventional etching and masking techniques known in the art and/or described herein. Set of fins 240 may include fins 242 in nFET region 206 and fins 244 in pFET region 208. Overlying each fin 242, 244 may be a hard mask (not shown), which can be formed according to known techniques to shield each fin 242, 244 in the set of fins during subsequent processing steps. It is understood that use of the hard mask over each fin 242, 244 is optional in some embodiments. The portions of fins 242, 244 where the hard mask is not employed, enables the subsequent formation of gate stacks (not shown) which will wrap around each fin 242, 244 as known in the art. Prior to forming the gate stack over the exposed fins 242, 244, fins 242, 244 may be lightly doped with dopants opposite of the transistor type which facilitate the formation of channel regions (not shown). Further, a dielectric 246 may be formed, e.g., via deposition, between each fin 242, 244 in set of fins 240 as shown in FIG. 18. Dielectric 246 may include, for example, an oxide, e.g., silicon dioxide, or a nitride, e.g., silicon nitride, or combinations thereof.

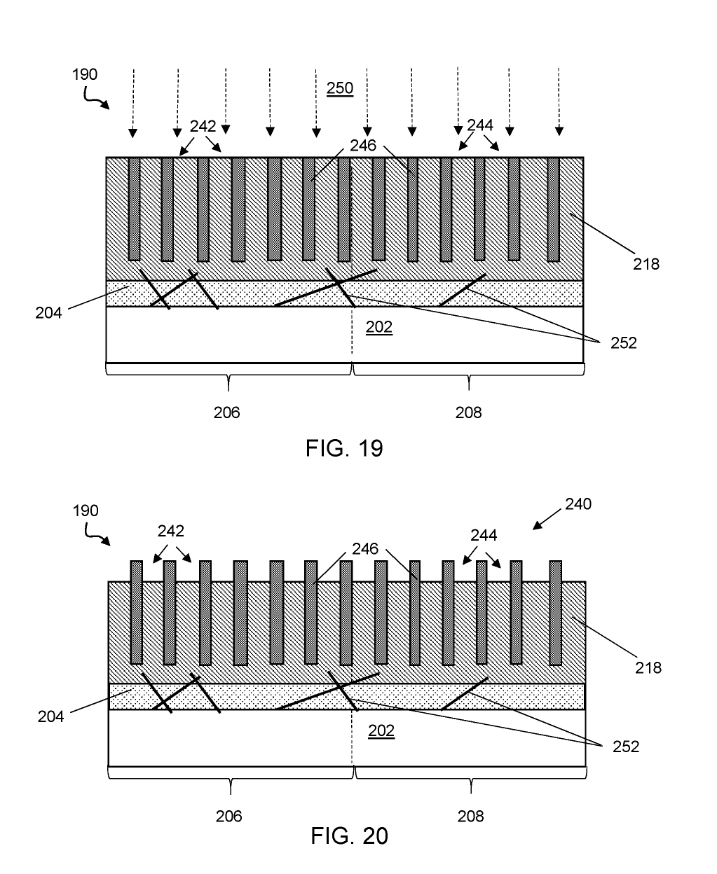

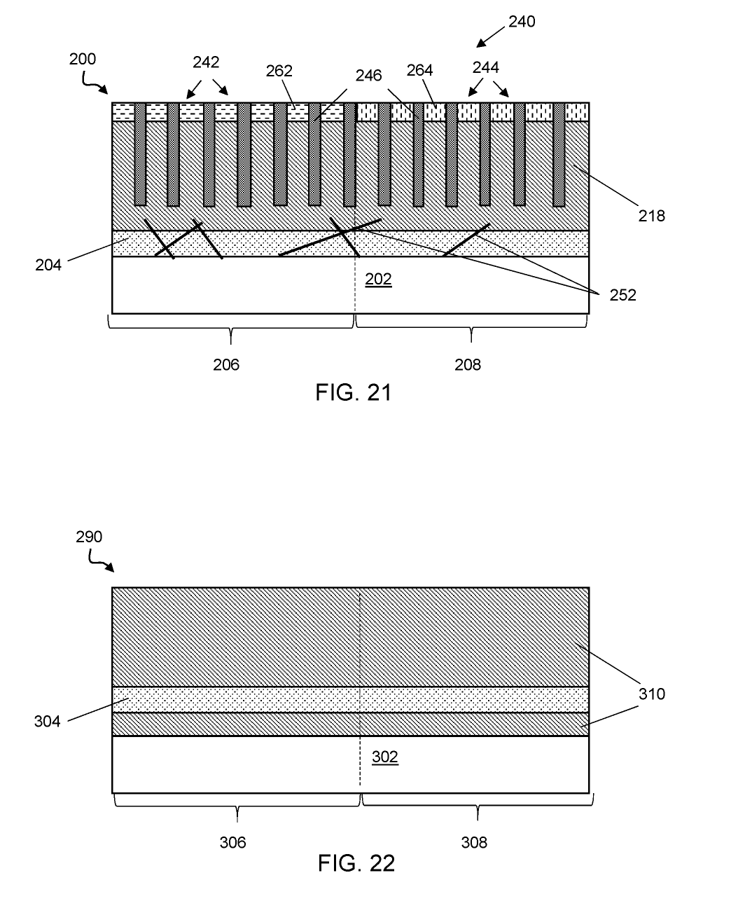

As shown in FIG. 19, an anneal 250 may be performed on semiconductor structure 200. Anneal 250 results in defects 216 (FIGS. 16-18) propagating through silicon germanium carbon layer 204 and strained silicon germanium layer 210 to form cracks 252. Anneal may be performed at a temperature of 800° C. to approximately 1100° C. for approximately 60 seconds to approximately 1200 seconds. Cracks 252 cause further decoupling of silicon germanium carbon layer 204 from substrate 202. This results in a strained silicon germanium layer 210 (FIGS. 15-18) becoming a relaxed silicon germanium layer 218. Referring now to FIG. 20, set of fins 240 may be recessed, e.g., via etching, such that each fin 242, 244 in set of fins 240 has a height less than that a height of each dielectric 246 therebetween. After fins 242, 244 are recessed, a strained silicon layer 262 may be formed over each fin 242, 244 in set of fins 240 as shown in FIG. 21. Further, strained silicon layer 262 may be patterned and etched to expose a portion of relaxed silicon germanium layer 218. For example, a mask (not shown) may be formed over strained silicon layer 262, patterned, and etched to expose portions of relaxed silicon germanium layer 218 thereunder as described with reference to FIGS. 4 and 13. More particularly, the mask may be etched to expose relaxed silicon germanium layer 218 in pFET region.

Still referring to FIG. 21, another strained silicon germanium layer 264 may be formed (e.g., epitaxial growth and/or deposition) over the exposed relaxed silicon germanium layer 218 as discussed with respect to FIG. 5. That is, strained silicon germanium layer 264 may be formed over relaxed silicon germanium layer 218 in pFET region 208. Strained silicon germanium layer 264 may include a high percent of germanium (approximately 40% to approximately 80%). While it has been shown and described as strained silicon layer 262 being formed prior to the formation of strained silicon germanium layer 264, it is to be understood that strained silicon germanium layer 264 may be formed prior to strained silicon layer 262 in other embodiments without departing from aspects of the disclosure. That is, strained silicon germanium layer 264 may be formed on relaxed silicon germanium layer 218 after the recessing of set of fins 240. Strained silicon germanium layer 264 may be patterned and etched as described herein to expose relaxed silicon germanium layer 218 in nFET region 206. Subsequently, strained silicon layer 262 may be formed over the exposed relaxed silicon germanium layer 218 in nFET region 206.

Referring now to FIGS. 22-26, a semiconductor structure 290 undergoing aspects of another method as described herein is shown. This embodiment is substantially similar to that which was described with respect to FIG. 15-19 except that the silicon germanium carbon layer is disposed within the strained silicon germanium layer, separated from the substrate.

As shown in FIG. 22, a strained silicon germanium layer 310 is formed, e.g., via epitaxial growth and/or deposition, on a substrate 302. Substrate 302 may include any of the materials listed herein relative to substrate 102 (FIG. 1). Strained silicon germanium layer 310 may include a low percentage of germanium. That is, strained silicon germanium layer 310 may include approximately 10% germanium to approximately 50% germanium, or more particularly 25% germanium. During formation of strained silicon germanium layer 310, a silicon germanium carbon layer 304 may be formed. That is, a first layer or set of layers of strained silicon germanium 310 may be formed. Then, a layer or set of layers of silicon germanium carbon 304 may be formed. Subsequently, a second layer or set of layers of strained silicon germanium 304 may be formed. Silicon germanium carbon layer 304 may include approximately 0.25% carbon to approximately 1.5% carbon. Strained silicon germanium layer 310 and silicon germanium carbon layer 304 may be formed by the process conditions discussed herein relative to FIG. 15.

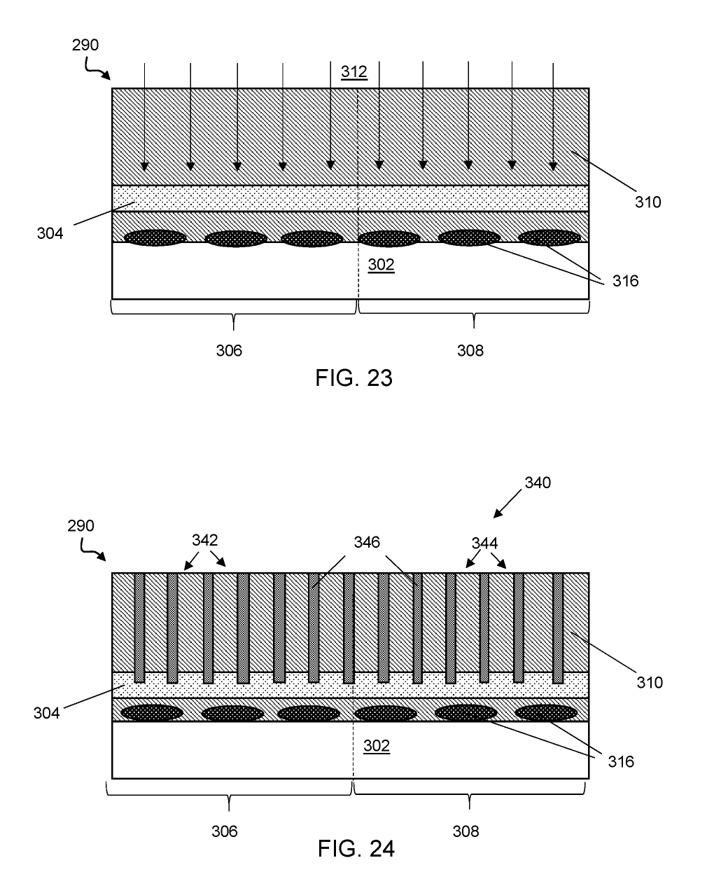

As shown in FIG. 23, an implanted species 312 may be implanted to a depth of the interface of strained silicon germanium layer 310 and the substrate 302. Implanted species 312 may be implanted at any of the process conditions discussed with respect to FIG. 16. Implanted species 312 may include, for example, at least one of: hydrogen (H₂) and helium (He). The implanting results in strained silicon germanium layer 310 decoupling from the crystal lattice of substrate 302 thereby causing defects 316.

As shown in FIG. 24, a set of fins 340 may be formed from strained silicon germanium layer 310 e.g., via conventional etching and masking techniques known in the art and/or described herein. Set of fins 340 may include fins 342 in nFET region 306 and fins 344 in pFET region 308. Overlying each fin 342, 344 may be a hard mask (not shown), which can be formed according to known techniques to shield each fin 342, 344 in the set of fins during subsequent processing steps. It is understood that use of the hard mask over each fin 342, 344 is optional in some embodiments. The portions of fins 342, 344 where the hard mask is not employed, enables the subsequent formation of gate stacks (not shown) which will wrap around each fin 342, 344 as known in the art. Prior to forming the gate stack over the exposed fins 342, 344, fins 342, 344 may be lightly doped with dopants opposite of the transistor type which facilitate the formation of channel regions (not shown). Further, a dielectric 346 may be formed, e.g., via deposition, between each fin 342, 344 in set of fins 340. Dielectric 346 may include, for example, an oxide, e.g., silicon dioxide, or a nitride, e.g., silicon nitride, or combinations thereof.

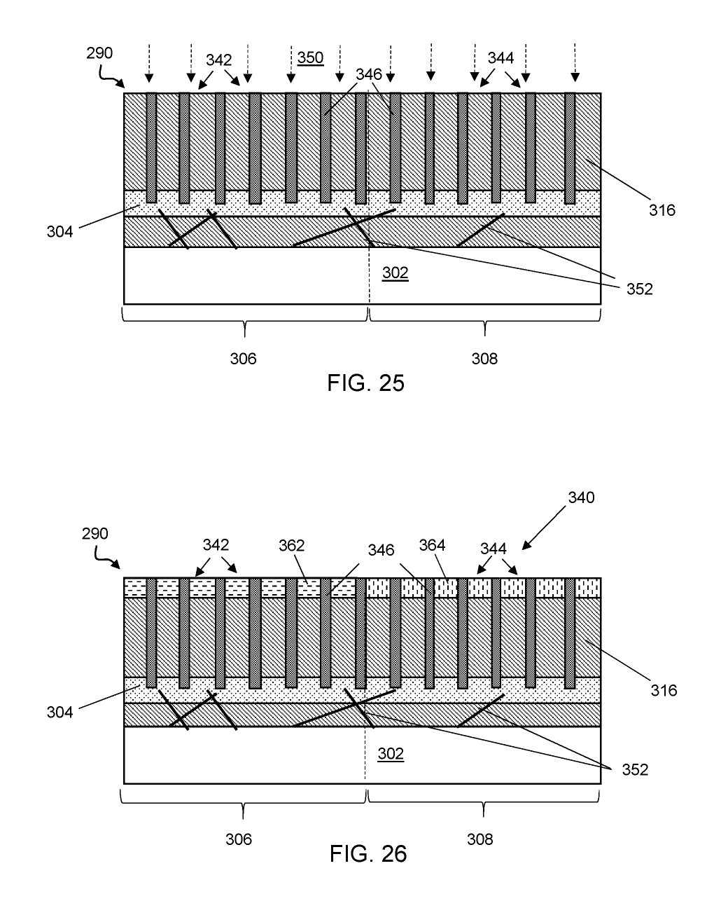

As shown in FIG. 25, an anneal 350 may be performed on semiconductor structure 290. Anneal 350 results in defects 316 (FIGS. 23-24) propagating through silicon germanium carbon layer 304 and strained silicon germanium layer 310 to form cracks 352. Cracks 352 cause further decoupling of strained silicon germanium 310 (FIGS. 22-24) layer 304 from substrate 302. This results in a strained silicon germanium layer 310 becoming a relaxed silicon germanium layer 318. Additionally, set of fins 340 may be recessed, e.g., via etching, such that each fin 342, 344 in set of fins 340 has a height less than that a height of each dielectric 346 therebetween.

Referring now to FIG. 26, after fins 342, 344 are recessed, a strained silicon layer 362 may be formed over each fin 342, 344 in set of fins 340. Further, strained silicon layer 324 may be patterned to expose a portion of relaxed silicon germanium layer 318. For example, a mask (not shown) may be formed over strained silicon layer 362 and etched to exposed portions of relaxed silicon germanium layer 318 thereunder. The mask may be etched to expose relaxed silicon germanium layer 318 in pFET region.

Another strained silicon germanium layer 364 may be formed (e.g., epitaxial growth and/or deposition) over the exposed relaxed silicon germanium layer 318 as discussed with respect to FIG. 5. That is, strained silicon germanium layer 364 may be formed over relaxed silicon germanium layer 318 in pFET region 308. Strained silicon germanium layer 364 may include a high percent of germanium (approximately 40% to approximately 80%). While it has been shown and described as strained silicon layer 362 being formed prior to the formation of strained silicon germanium layer 364, it is to be understood that strained silicon germanium layer 364 may be formed prior to strained silicon layer 362 in other embodiments without departing from aspects of the disclosure. That is, strained silicon germanium layer 364 may be formed on relaxed silicon germanium layer 318 after the recessing of set of fins 340. Strained silicon germanium layer 364 may be patterned as described herein to expose relaxed silicon germanium layer 318 in nFET region 306. Subsequently, strained silicon layer 362 may be formed over the relaxed strained silicon germanium layer 318 in nFET region 306.

With respect to the embodiments shown and described with respect to FIGS. 15-26, it is to be understood that in some embodiments, silicon germanium carbon layer 304 may not be included and does not depart from aspects of the disclosure as described herein.

The methods as described above are used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A method of fabricating a semiconductor structure, the method comprising:
forming a relaxed silicon germanium superlattice over a substrate;
forming a set of fins within the relaxed silicon germanium superlattice;
forming a dielectric between each fin in the set of fins;
forming a strained silicon layer over a first portion of the set of fins and the dielectric between each fin in the first portion of the set of fins; and
forming a strained silicon germanium layer over a second portion of the set of fins and the dielectric between each fin in the second portion of the set of fins.

2. The method of claim 1, wherein the forming the relaxed silicon germanium superlattice on the substrate includes:
forming alternating germanium layers and silicon layers.

3. The method of claim 1, wherein the relaxed silicon germanium superlattice includes a thickness of approximately 10 nanometers (nm) to approximately 1000 nm.

4. The method of claim 1, wherein a composition of the relaxed silicon germanium superlattice includes approximately 25% germanium.

5. The method of claim 1, further comprising:
performing an anneal after the forming of a silicon germanium superlattice to form a relaxed silicon germanium superlattice prior to the forming of the set of fins.

6. The method of claim 5, further comprising:
removing a portion of the strained silicon layer prior to the forming of the strained silicon germanium layer.

7. The method of claim 1, wherein the forming the strained silicon layer includes forming the strained silicon layer over a n-type field effect transistor (nFET) region, and the forming the strained silicon germanium layer includes forming the strained silicon germanium layer over a p-type field effect transistor (pFET) region.

8-20. (canceled)
